(19) United States
(12) Patent Application Publication
(10) Pub. No.: US 2024/0329423 A1
(43) Pub. Date: Oct. 3, 2024

(54) DISPLAY SYSTEM

(71) Applicant: ELECTRONICS AND TELECOMMUNICATIONS RESEARCH INSTITUTE, Daejeon (KR)

(72) Inventors: CHUNWON BYUN, Daejeon (KR); Woongseob Han, Daejeon (KR); Jae-Hyeung Park, Daejeon (KR); Jiyun Han, Daejeon (KR); Chan-mo Kang, Daejeon (KR); Jin Wook Shin, Daejeon (KR); Dae Hyun Ahn, Daejeon (KR)

(21) Appl. No.: 18/504,759

(22) Filed: Nov. 8, 2023

(30) Foreign Application Priority Data
Mar. 30, 2023 (KR) 10-2023-0041675

(51) Int. Cl. G02B 30/26

(52) U.S. Cl. CPC G02B 30/26; H01L 33/58; H10K 59/879

(57) ABSTRACT

Disclosed is a display system, which includes a display including a pixel array having a plurality of pixels and that outputs a raw video, a shutter array including a plurality of shutters respectively corresponding to the plurality of pixels and that sequentially outputs a plurality of shuttered images respectively corresponding to a plurality of areas on the pixel array based on the raw video, and a variable focus lens that operates based on depth information corresponding to each of the plurality of shuttered images.

### CROSS-REFERENCE TO RELATED APPLICATIONS

This application claims priority under 35 U.S.C. § 119 to Korean Patent Application No. 10-2023-0041675 filed on Mar. 30, 2023, in the Korean Intellectual Property Office, the disclosures of which are incorporated by reference herein in their entireties.

### BACKGROUND

Embodiments of the present disclosure described herein relate to a display system. More particularly, embodiments of the present disclosure described herein relate to a display system that provides a natural three-dimensional image.

Recently, various types of display systems are being studied as output means of virtual reality and augmented reality. In particular, in recent years, various types of display systems such as micro lens array-based display systems and super multi-view image reproduction technology-based display systems are being studied to output three-dimensional (3D) images.

However, these technologies may entail a problem of requiring an excessively high display resolution or an excessively high display frame rate for natural reproduction of 3D images.

### SUMMARY

Embodiments of the present disclosure are to solve the above-mentioned technical problem. More particularly, embodiments of the present disclosure provide a display system that outputs a high-quality 3D image even through a display with a relatively low frame rate.

According to an embodiment of the present disclosure, a display system includes a display including a pixel array having a plurality of pixels and that outputs a raw video, a shutter array including a plurality of shutters respectively corresponding to the plurality of pixels and that sequentially outputs a plurality of shuttered images respectively corresponding to a plurality of areas on the pixel array based on the raw video, and a variable focus lens that operates based on depth information corresponding to each of the plurality of shuttered images.

According to an embodiment, the shutter array may output a first shuttered image corresponding to a first area of the pixel array at a first time, and may output a second shuttered image corresponding to a second area of the pixel array at a second time after the first time.

According to an embodiment, a focal length of the variable focus lens at the first time may be a first length value, and a focal length of the variable focus lens at the second time may be a second length value.

According to an embodiment, when depth information corresponding to the first shuttered image is a first depth value and depth information corresponding to the second shuttered image is a second depth value greater than the first depth value, the first length value may be less than the second length value.

According to an embodiment, a time interval between the plurality of shuttered images may be determined based on the number of the plurality of areas.

According to an embodiment, a sub-frame rate with respect to the plurality of shuttered images may be greater than a product of the number of the plurality of areas and ‘30 Hz’.

According to an embodiment, the variable focus lens may change the focal length discontinuously.

According to an embodiment, the shutter array may sequentially output the plurality of shuttered images based on a first order depending on a location of each of the plurality of shuttered images on the pixel array.

According to an embodiment, the variable focus lens may continuously change a focal length.

According to an embodiment, the shutter array may sequentially output the plurality of shuttered images based on a second order depending on the depth information of each of the plurality of shuttered images.

According to an embodiment, the shutter array may be disposed between the display and the variable focus lens.

According to an embodiment, the display may include at least one of an OLED, an LED, and a micro LED.

According to an embodiment of the present disclosure, a display system includes a display including a pixel array having a plurality of pixels, a shutter array including a plurality of shutters respectively corresponding to the plurality of pixels and that passes a first area of the pixel array and shutters a second area different from the first area, and a variable focus lens that operates based on depth information of an image corresponding to the first area.

According to an embodiment, the shutter array may be disposed between the display and the variable focus lens.

According to an embodiment, a focal length of the variable focus lens may be determined based on the depth information.

According to an embodiment, the second area may be an area remaining except for the first area in the pixel array.

### BRIEF DESCRIPTION OF THE FIGURES

The above and other objects and features of the present disclosure will become apparent by describing in detail embodiments thereof with reference to the accompanying drawings.

FIG. 1 is a diagram illustrating a display system according to an embodiment.

FIG. 2 is a diagram illustrating a display system according to an embodiment of the present disclosure.

FIG. 3 is a diagram illustrating an operation of the display system of FIG. 2.

FIGS. 4A and 4B are diagrams illustrating an operation of a display system of FIG. 3 in more detail.

FIGS. 5A and 5B illustrate an order of a plurality of subframes according to a method of changing a focal length of a variable focus lens.

FIG. 6 is a diagram illustrating a display system according to an embodiment.

### DETAILED DESCRIPTION

Hereinafter, embodiments of the present disclosure will be described clearly and in detail such that those skilled in the art may easily carry out the present disclosure. Specific details such as detailed components and structures are merely provided to assist the overall understanding of the embodiments of the present disclosure. Therefore, it should be apparent to those skilled in the art that various changes and modifications of the embodiments described herein may be made without departing from the scope and spirit of the present disclosure. Moreover, descriptions of well-known functions and structures will be omitted for clarity and conciseness. In the following drawings or in the detailed description, components may be connected with any other components except for components illustrated in a drawing or described in the detailed description. The terms used in the specification are terms defined in consideration of the functions in the present disclosure and are not limited to a specific function. The definitions of the terms should be determined based on the contents throughout the specification.

Components that are described in the detailed description with reference to the terms “driver”, or block”, etc. will be implemented with software, hardware, or a combination thereof. For example, the software may be a machine code, firmware, an embedded code, and application software. For example, the hardware may include an electrical circuit, an electronic circuit, a processor, a computer, integrated circuit cores, a pressure sensor, an inertial sensor, a microelectromechanical system (MEMS), a passive element, or a combination thereof.

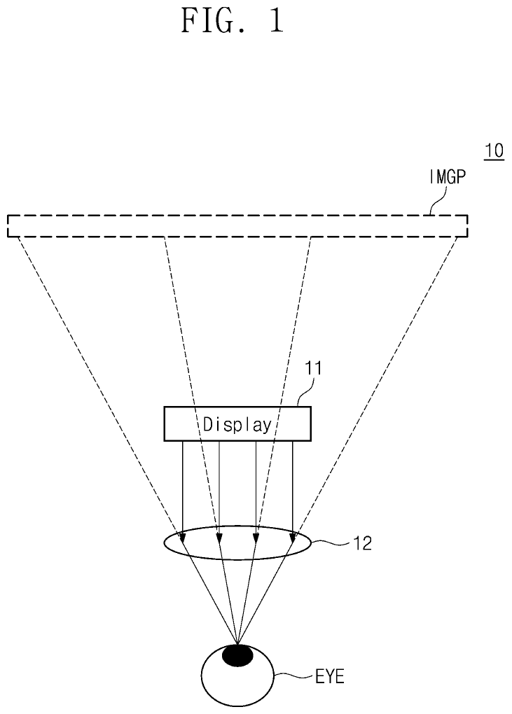

FIG. 1 is a diagram illustrating a display system according to an embodiment. Referring to FIG. 1, a display system 10 may include a display 11 and a convex lens 12. In this case, the convex lens 12 may be disposed between the display 11 and a user's eye EYE.

The display 11 may output an image to the user's eye EYE through the convex lens 12. In this case, the convex lens 12 may refract the image output from the display 11 and provide it to the user's eye EYE. In this case, the user's eye EYE may recognize that an image is output on an image plane IMGP based on an image received after being refracted through the convex lens 12.

The length to the image plane IMGP perceived by the user may be determined based on the focal length of the convex lens 12. Accordingly, according to the display system 10 of an embodiment of FIG. 1, only 2D images having fixed depth information may be output.

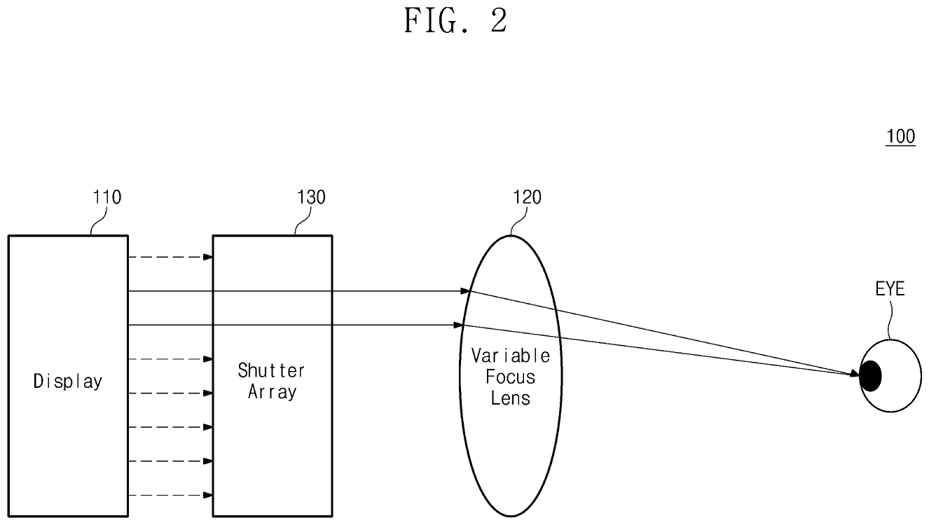

FIG. 2 is a diagram illustrating a display system according to an embodiment of the present disclosure. Referring to FIG. 2, a display system 100 may include a display 110, a variable focus lens 120, and a shutter array 130. In this case, the variable focus lens 120 may be disposed between the display 110 and the user's eye EYE.

For a more concise description, an embodiment in which the shutter array 130 is disposed between the display 110 and the variable focus lens 120 will be representatively described below. However, the scope of the present disclosure is not limited to a specific arrangement of the shutter array 130.

The display 11 may include a pixel array. The pixel array may include a plurality of pixels arranged in a row direction and a column direction. In this case, each of the plurality of pixels may include one or more of an LED, an OLED, and a micro LED. However, the scope of the present disclosure is not limited to how the display 11 is implemented. In detail, according to an embodiment of the present disclosure, any type of display device may be used as the display 11.

The display 11 may output an image to the user's eye EYE through the shutter array 130 and the variable focus lens 120. In this case, an image output by the display 11 will be referred to as a raw video. In addition, each of the frames constituting the raw video will be referred to as a raw image.

The shutter array 130 may include a plurality of shutters arranged in row and column directions. For example, each of a plurality of shutters may shutter an optical signal output from a plurality of pixels of a pixel array.

The shutter array 130 may shutter a partial area of a raw image output from the display 110. In contrast, the shutter array 130 may pass a partial area of the raw image output from the display 110. In an embodiment, an area of the raw image that is passed by the shutter array 130 may correspond to an area of the raw image that is not shuttered by the shutter array 130. In detail, according to an embodiment of the present disclosure, only a partial area of the raw image output from the display 110 may be provided to the variable focus lens 120. Hereinafter, for more concise description, an image provided through the variable focus lens 120 will be referred to as a ‘shuttered image’.

In an embodiment, the shutter array 130 may continuously change the area to be shuttered of the raw image. In detail, the shutter array 130 may be configured to output a first shuttered image corresponding to a first area of the pixel array at a first time, and to output a second shuttered image corresponding to a second area of the pixel array at a second time. In this case, the area of the pixel array corresponding to the shuttered image provided through the variable focus lens 120 may change in time series.

The variable focus lens 120 may refract the shuttered image and provide it to the user's eyes EYE. In this case, the user's eyes EYE may recognize that an image is output to a space beyond the display 110 based on an image received after being refracted through the variable focus lens 120.

A focal length of the variable focus lens 120 may vary depending on a shuttered image. For example, when a first shuttered image is provided, the focal length of the variable focus lens 120 may have a first length value, and when a second shuttered image is provided, the focal length of the variable focus lens 120 may have a second length value. In detail, the variable focus lens 120 may be configured to change the focal length based on depth information corresponding to the received shuttered image. When the focal length of the variable focus lens 120 is changed, the depth of an image recognized by the user's eyes (EYE) may be changed. The relationship between the depth information and the focal length will be described in detail with reference to the following drawings.

The focal length of the variable focus lens 120 may vary for each received shuttered image. In this case, the user's eye EYE may differently recognize the depth of each of the shuttered images sequentially provided through the shutter array 130. Accordingly, according to the present disclosure, the display system 100 providing a natural 3D image to a user may be provided.

In an embodiment, the variable focus lens 120 may be configured to continuously change the focal length. For example, the variable focus lens 120 may be configured to continuously change a shape of the lens using an optical fluid and a polymer separator. However, the scope of the present disclosure is not limited thereto.

In an embodiment, the variable focus lens 120 may be configured to change the focal length discretely. For example, the variable focus lens 120 may be configured to discontinuously change the focus by overlapping a static geometric lens and an electrically turned on/off half wave plate in several layers. However, the scope of the present disclosure is not limited thereto.

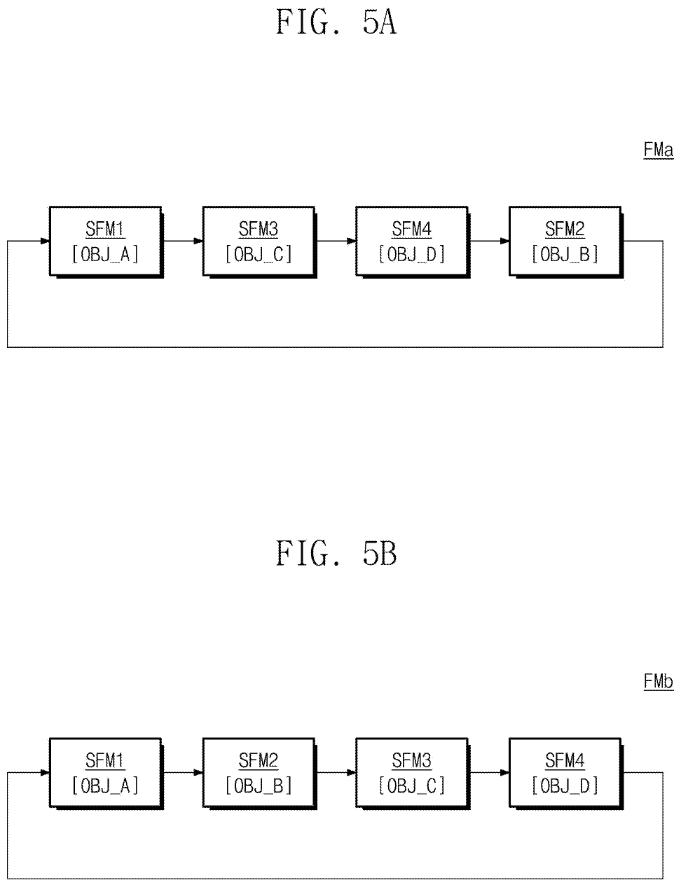

In an embodiment, the operating method of the shutter array 130 may vary according to the implementation method of the variable focus lens 120. The operation method of the shutter array 130 according to the implementation method of the variable focus lens 120 will be described in more detail with reference to FIGS. 5A and 5B below.

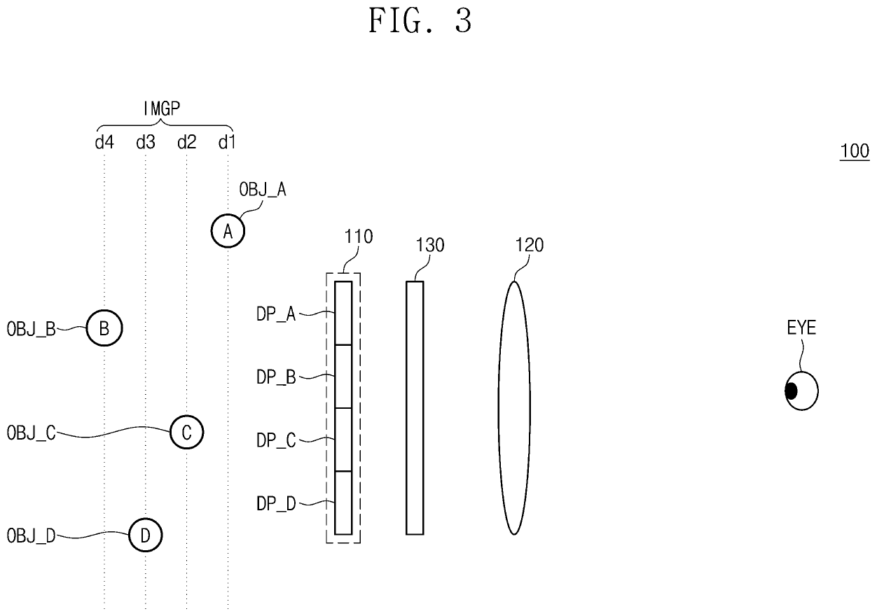

FIG. 3 is a diagram illustrating an operation of the display system of FIG. 2. Hereinafter, for a more concise description, an embodiment in which a pixel array of the display 110 is divided into four areas displaying different objects will be representatively described. However, the scope of the present disclosure will not be limited to the number of areas into which the pixel array of display 110 is divided.

The display 110 may include first to fourth display areas DP_A to DP_D. In this case, each of the first to fourth display areas DP_A to DP_D may display different objects. For example, the first display area DP_A may display a first object OBJ_A, the second display area DP_B may display a second object OBJ_B, the third display area DP_C may display a third object OBJ_C, and the fourth display area DP_A may display a fourth object OBJ_D.

More specifically, the first display area DP_A may provide an area corresponding to the first object OBJ_A of the raw image to the user's eye EYE through the shutter array 130 and the variable focus lens 120. In this case, the user may recognize that the first object OBJ_A is displayed in a space beyond the display 110. Operations of the second to fourth display areas DP_B to DP_D are similar to those of the previously described first display area DP_A, so additional descriptions will be omitted to avoid redundancy.

In an embodiment, the first object OBJ_A to the fourth object OBJ_D may correspond to different depth information. In detail, to provide a 3D image with a high sense of immersion to the user, when the first object OBJ_A to the fourth object OBJ_D are recognized by the user's eyes EYE, they may need to be recognized as being separated by different lengths from each other. For example, the first object OBJ_A may have to be recognized as being separated from the user by a first length d1, the second object OBJ_B may have to be recognized as being separated from the user by a fourth length d4, the third object OBJ_C may have to be recognized as being separated from the user by a second length d2, and the fourth object OBJ_D may have to be recognized as being separated from the user by a third length d3.

In an embodiment, the first length d1 may be greater than the second length d2, the second length d2 may be greater than the third length d3, and the third length d3 may be greater than the fourth length d3. However, the scope of the present disclosure is not limited thereto.

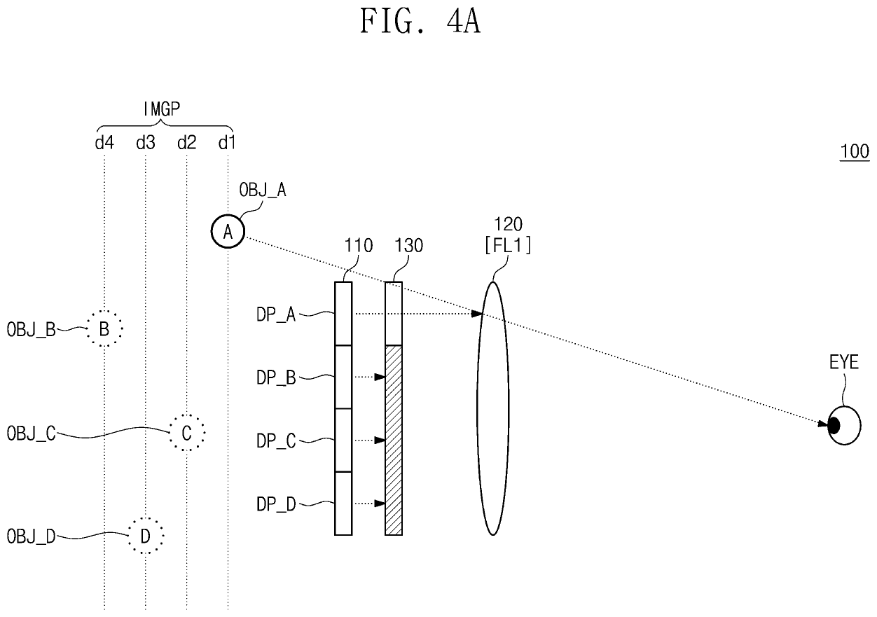

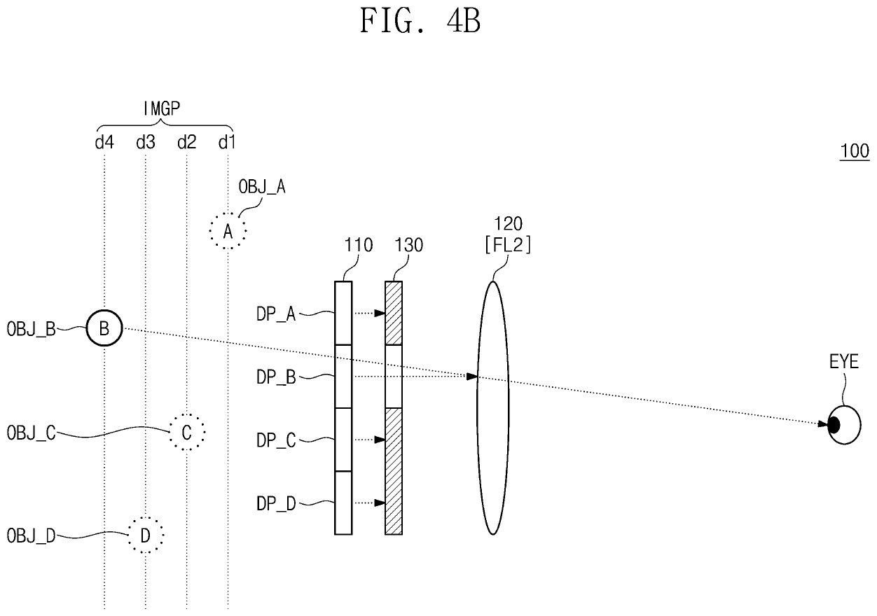

According to an embodiment of the present disclosure, the shutter array 130 may be implemented to sequentially output shuttered images corresponding to one of the first to fourth display areas DP_A to DP_D, and the variable focus lens 120 may be implemented to change the focal length to correspond to the depth information of the received shuttered image. In this case, a 3D image with high sense of immersion may be provided to the user. Detail operations of the shutter array 130 and the variable focus lens 120 will be described in detail with reference to FIGS. 4A and 4B below.

FIGS. 4A and 4B are diagrams illustrating an operation of a display system of FIG. 3 in more detail. Hereinafter, an operation of the shutter array 130 and the variable focus lens 120 at two time points in which the display system 100 shows different objects will be representatively described with reference to FIGS. 4A and 4B.

First, referring to FIGS. 3 and 4A, at a first time, the display system 100 may provide an image corresponding to the first object OBJ_A to the user. For example, the shutter array 130 may pass optical signals from the first display area DP_A and may shutter optical signals from the second to fourth display areas DP_B to DP_D. In this case, the shuttered image provided to the variable focus lens 120 at the first time may be an image generated from the first display area DP_A. In detail, the shuttered image provided to the variable focus lens 120 at the first time may include only the first object OBJ_A among the first to fourth objects OBJ_A to OBJ_D.

In this case, the variable focus lens 120 may adjust the focal length such that the user's eye EYE may recognize that the first object OBJ_A is separated by a depth value corresponding to the first object OBJ_A (i.e., the first length d1). Hereinafter, for more concise description, it is assumed that the focal length at which the user's eyes EYE may recognize that the object is separated by the first length d1 is a first focal length value FL1.

In detail, according to an embodiment of the present disclosure, the variable focus lens 120 may adjust the focal length according to the depth information corresponding to received shuttered images.

Next, referring to FIGS. 3 and 4B, at a second time, the display system 100 may provide an image corresponding to the second object OBJ_B to the user. For example, the shutter array 130 may pass optical signals from the second display area DP_B and may shutter optical signals from the first, third, and fourth display areas DP_A, DP_C, and DP_D. In this case, the shuttered image provided to the variable focus lens 120 at the second time may be an image generated from the second display area DP_B. In detail, the shuttered image provided to the variable focus lens 120 at the second time may include only the second object OBJ_B among the first to fourth objects OBJ_A to OBJ_D.

In this case, the variable focus lens 120 may adjust the focal length such that the user's eye EYE may recognize that the second object OBJ_B is separated by a depth value corresponding to the second object OBJ_B (i.e., the fourth length d4). Hereinafter, for more concise description, it is assumed that the focal length at which the user's eyes EYE may recognize that the object is separated by the fourth length d4 is a second focal length value FL2.

In an embodiment, the first length d1 may be less than the fourth length d4. That is, the first object OBJ_A may need to be recognized by the user as closer than the second object OBJ_B. In this case, the first focal length FL1 may be less than the second focal length FL2. However, the scope of the present disclosure is not limited thereto.

Also, in a similar manner, the display system 100 may sequentially provide images corresponding to the third and fourth objects OBJ_C and OBJ_D to the user. In this case, the user will recognize that the first to fourth objects OBJ_A to OBJ_D are separated by different lengths from each other. Accordingly, according to an embodiment of the present disclosure, since images corresponding to different depth information may be sequentially provided to a user, a 3D image with a sense of immersion may be provided to the user.

In an embodiment, a unit in which shuttered images corresponding to the first to fourth display areas DP_A to DP_D are provided to the user's eye EYE through the variable focus lens 120 once each is referred to as a ‘frame’. In detail, in a single frame, the user's eyes EYE may recognize the first object OBJ_A to the fourth object OBJ_D once.

In an embodiment, a unit in which a shuttered image corresponding to one of the first to fourth display areas DP_A to DP_D is provided to the user's eye EYE through the variable focus lens 120 is referred to as a ‘subframe’. In this case, in a single subframe, the user's eye EYE may recognize one of the first object OBJ_A to the fourth object OBJ_D. For example, one ‘frame’ may include four subframes respectively corresponding to the first to fourth display areas DP_A to DP_D.

In an embodiment, the order of a plurality of subframes included in a single frame may be determined based on a method for changing the focal length of the variable focus lens 120. The order of the plurality of subframes according to the method of changing the focal length of the variable focus lens 120 will be described in detail with reference to FIGS. 5A and 5B below.

FIGS. 5A and 5B illustrate an order of a plurality of subframes according to a method of changing a focal length of a variable focus lens. Hereinafter, an order of a plurality of subframes in the case where the variable focus lens 120 continuously changes the focal length will be described with reference to FIG. 5A, and an order of the plurality of subframes in the case where the variable focus lens 120 discontinuously changes the focal length will be described with reference to FIG. 5B. However, the scope of the present disclosure is not limited thereto.

First, referring to FIGS. 3 and 5A, a time-sequential order of a plurality of subframes may be determined based on an object depth order. For example, a first frame FMa may include first to fourth subframes SFM1 to SFM4. The first subframe SFM1 may include an image corresponding to the first object OBJ_A, the second subframe SFM2 may include an image corresponding to the second object OBJ_B, the third subframe SFM3 may include an image corresponding to the third object OBJ_C, and the fourth subframe SFM4 may include an image corresponding to the fourth object OBJ_D. In this case, the time-sequential order of the first to fourth subframes SFM1 to SFM4 may be determined according to the depth information of the first to fourth objects OBJ_A to OBJ_D respectively corresponding to the first to fourth subframes SFM1 to SFM4.

More specifically, as described above with reference to FIG. 3, the first object OBJ_A may correspond to depth information representing the first length d1, the second object OBJ_B may correspond to depth information representing the fourth length d4, the third object OBJ_C may correspond to depth information representing the second length d2, and the fourth object OBJ_D may correspond to depth information representing the third length d3. In this case, the time-sequential order of the first to fourth subframes SFM1 to SFM4 may be determined in ascending or descending order of depth values (i.e., first to fourth lengths d1 to d4) indicated by the depth information. In detail, the order of the first to fourth subframes SFM1 to SFM4 included in the first frame FMa may be arranged in the order of the first subframe SFM1, the third subframe SFM3, the fourth subframe SFM4, and the second subframe SFM2.

In an embodiment, after the first to fourth subframes SFM1 to SFM4 are provided to the user's eye EYE once, the first subframe SFM1 corresponding to the first object OBJ_A may be repeatedly provided. However, the scope of the present disclosure is not limited thereto.

In detail, according to an embodiment of the present disclosure, when the variable focus lens 120 continuously changes the focal length, the time-sequential order of the plurality of subframes may be determined according to depth information of an object represented by each of the subframes. In this case, it may be easier to express a natural 3D image.

Next, referring to FIGS. 3 and 5B, a time-sequential order of a plurality of subframes may be determined based on a location of an object. For example, the second frame FMb may include the first to fourth subframes SFM1 to SFM4. The time-sequential order of the first to fourth subframes SFM1 to SFM4 may be determined based on locations on the pixel array of the display 110. For a more concise description, additional description with respect to the first to fourth subframes SFM1 to SFM4 and the depth information of the first to fourth objects OBJ_A to OBJ_D that are previously described will be omitted to avoid redundancy.

As described above with reference to FIG. 3, each of the first to fourth objects OBJ_A to OBJ_D may be displayed through different areas of the display 110. For example, the first object OBJ_A may be displayed through the first display area DP_A, the second object OBJ_B may be displayed through the second display area DP_B, the third object OBJ_C may be displayed through the third display area DP_C, and the fourth object OBJ_D may be displayed through the fourth display area DP_D. Hereinafter, for a more concise description, it is assumed that the first display area DP_A is adjacent to the second display area DP_B, the second display area DP_B is adjacent to the first display area DP_A and the third display area DP_C, the third display area DP_C is adjacent to the second display area DP_B and the fourth display area DP_D, and the fourth display area DP_D is adjacent to the third display area DP_C.

In this case, the time-sequential order of the first to fourth subframes SFM1 to SFM4 may be determined depending on whether objects adjacent to each other are output through which display area (i.e., a location on the pixel array of the display). In detail, the order of the first to fourth subframes SFM1 to SFM4 included in the second frame FMb may be arranged in the order of the first subframe SFM1, the second subframe SFM2, the third subframe SFM3, and the fourth subframe SFM4.

In an embodiment, after the first to fourth subframes SFM1 to SFM4 are provided to the user's eye EYE once, the first subframe SFM1 corresponding to the first object OBJ_A may be repeatedly provided. However, the scope of the present disclosure is not limited thereto.

In detail, according to an embodiment of the present disclosure, when the variable focus lens 120 discontinuously changes the focal length, the time-sequential order of the plurality of subframes may be determined according to the location of an object represented by each of the subframes. In this case, the shutter array 130 may operate more stably.

In an embodiment, the time interval between the first to fourth subframes SFM1 to SFM4 may be determined based on Equation 1 below.

$$T < \frac{1}{{N}_{DP} \times 30} \qquad [ Equation 1 ]$$

In this case, ‘T’ may represent a time interval between subframes, and N_{DP} may represent the number of areas of the display 110. In an embodiment, a number of ‘30’ may correspond to 30 fps, which is a critical frame rate at which the human eye cannot perceive a change.

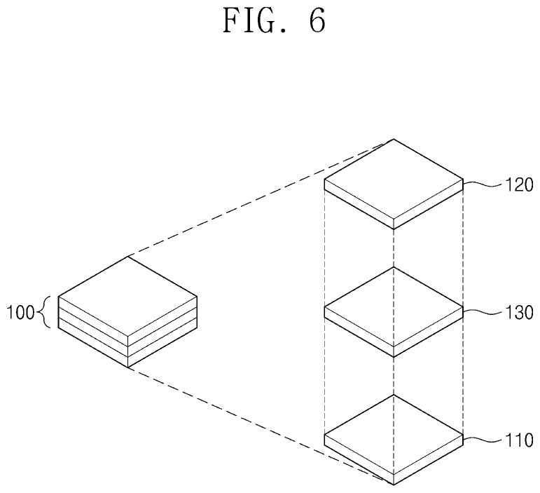

FIG. 6 is a diagram illustrating a display system according to an embodiment. Referring to FIG. 6, the display system 100 may include the display 110, the variable focus lens 120, and the shutter array 130. Since the configuration and functions of the display 110, the variable focus lens 120, and the shutter array 130 have been described in detail above, additional descriptions will be omitted to avoid redundancy.

In an embodiment, the display system 100 may be implemented as a single package structure. For example, the shutter array 130 may be stacked on the display 110. In this case, the plurality of shutters of the shutter array 130 may correspond to a plurality of pixels included in the pixel array of the display 110, respectively. The variable focus lens 120 may be stacked on the shutter array 130. In this case, the shutter array 130 will be disposed between the display 110 and the variable focus lens 120. However, the scope of the present disclosure is not limited thereto.

According to an embodiment of the present disclosure, a display system that outputs a high-quality 3D image while using a conventional display may be provided. In addition, according to an embodiment of the present disclosure, binocular parallax and monocular parallax are matched, so that fatigue of a user that may occur when using a conventional near eye display system may be reduced.

The above description refers to embodiments for implementing the present disclosure Embodiments in which a design is changed simply or which are easily changed may be included in the present disclosure as well as an embodiment described above. In addition, technologies that are easily changed and implemented by using the above embodiments may be included in the present disclosure. While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display system comprising:
a display including a pixel array having a plurality of pixels and configured to output a raw video;
a shutter array including a plurality of shutters respectively corresponding to the plurality of pixels and configured to sequentially output a plurality of shuttered images respectively corresponding to a plurality of areas on the pixel array based on the raw video; and
a variable focus lens configured to operate based on depth information corresponding to each of the plurality of shuttered images.

2. The display system of claim 1, wherein the shutter array is configured to:
output a first shuttered image corresponding to a first area of the pixel array at a first time, and
output a second shuttered image corresponding to a second area of the pixel array at a second time after the first time.

3. The display system of claim 2, wherein a focal length of the variable focus lens at the first time is a first length value, and
wherein a focal length of the variable focus lens at the second time is a second length value.

4. The display system of claim 3, wherein, when depth information corresponding to the first shuttered image is a first depth value and depth information corresponding to the second shuttered image is a second depth value greater than the first depth value, the first length value is less than the second length value.

5. The display system of claim 1, wherein a time interval between the plurality of shuttered images is determined based on the number of the plurality of areas.

6. The display system of claim 5, wherein a sub-frame rate with respect to the plurality of shuttered images is greater than a product of the number of the plurality of areas and ‘30 Hz’.

7. The display system of claim 1, wherein the variable focus lens is configured to change the focal length discontinuously.

8. The display system of claim 7, wherein the shutter array is configured to:
sequentially output the plurality of shuttered images based on a first order depending on a location of each of the plurality of shuttered images on the pixel array.

9. The display system of claim 1, wherein the variable focus lens is configured to continuously change a focal length.

10. The display system of claim 9, wherein the shutter array is configured to:
sequentially output the plurality of shuttered images based on a second order depending on the depth information of each of the plurality of shuttered images.

11. The display system of claim 1, wherein the shutter array is disposed between the display and the variable focus lens.

12. The display system of claim 1, wherein the display includes at least one of an OLED, an LED, and a micro LED.

13. A display system comprising:
a display including a pixel array having a plurality of pixels;
a shutter array including a plurality of shutters respectively corresponding to the plurality of pixels, configured to pass a first area of the pixel array and to shutter a second area different from the first area; and
a variable focus lens configured to operate based on depth information of an image corresponding to the first area.

14. The display system of claim 13, wherein the shutter array is disposed between the display and the variable focus lens.

15. The display system of claim 13, wherein a focal length of the variable focus lens is determined based on the depth information.

16. The display system of claim 13, wherein the second area is an area remaining except for the first area in the pixel array.
